(19) United States
(12) Patent Application Publication
(10) Pub. No.: US 2026/0372032 A1
(43) Pub. Date: Nov. 19, 2026

(54) GATE STRUCTURES AND METHODS OF FORMING

(71) Applicant: Taiwan Semiconductor Manufacturing Co., Ltd., Hsinchu (TW)

(72) Inventors: Hung-Yao Chen, Hsinchu (TW); Shun-Siang Jhan, Kaohsiung City (TW); Ta-Chun Ma, New Taipei City (TW); Hsueh-Chang Sung, Zhubei City (TW); Ming-Hua Yu, Hsinchu (TW); Chii-Horng Li, Zhubei City (TW)

(21) Appl. No.: 19/749,795

(22) Filed: Jul. 22, 2026

Related U.S. Application Data
(63) Continuation of application No. 18/940,211, filed on Nov. 7, 2024.

(51) Int. Cl. H10P 95/90; H10D 30/01; H10D 30/43; H10D 30/67; H10D 62/10; H10D 64/01

(52) U.S. Cl. CPC H10P 95/906; H10D 30/014; H10D 30/43; H10D 30/6735; H10D 30/6757; H10D 62/121; H10D 64/017; H10D 64/018

(57) ABSTRACT

A method includes forming a plurality of nanostructures, the plurality of nanostructures comprising first nanostructures that are alternatingly stacked with second nanostructures and removing the first nanostructures from the plurality of nanostructures to define recesses between the second nanostructures. The method further includes after removing the first nanostructures, performing a surface repair process on the second nanostructures and forming a gate structure in the recesses around the second nanostructures. The surface repair process increases a curvature of surfaces of the second nanostructures in the recesses.

### CROSS-REFERENCE TO RELATED APPLICATIONS

This application is a continuation of U.S. application Ser. No. 18/940,211, filed on Nov. 7, 2024, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 9C, 9D, 10A, 10B, 10C, 10D, 11A, 11B, 12A, 12B, 13A, 13B, 14A, 14B, 14C, 15A, 15B, 15C, 15D, 15E, 15F, 15G, 15H, 15I, 16A, 16B, 16C, 16D, 16E, 16F, 16G, 16H, 17A, 17B, 17C, 18A, 18B, 18C, 19A, 19B, and 19C illustrate varying views of intermediary steps of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a stack of nanostructures is formed that includes first nanostructures alternatingly stacked with second nanostructures. The second nanostructures are subsequently replaced with a gate structure that surrounds the first nanostructures. Removing the second nanostructures may result in a residue (e.g., a semiconductor material residue, such as germanium intermix residue) remaining on surfaces of the first nanostructures, and a cleaning process (e.g., a wet cleaning) may be used to fully remove the residue and improve the electrical performance of the resulting device. However, the cleaning process may increase a surface roughness of the first nanostructures and/or over etch the first nanostructures.

Various embodiments perform a surface repair process on the first nanostructures to improve the surface property and/or profile of the first nanostructures. The surface repair process may include an anneal process and/or a semiconductor re-deposition process that increases the roundness of the first nanostructures and reduces roughness of the first nanostructures. As a result, various embodiments provide reduced surface residue and improved device performance (e.g., reduced current crowding effect (CCE) at corners between the first nanostructures and the gate structures). Further, the surface repair process may be used to define a desired profile of the gate structures to achieve a desired threshold voltage.

Embodiments are described below in a particular context, a die comprising nano-FETs. Various embodiments may be applied, however, to dies comprising other types of transistors (e.g., stacking transistors, or the like) in lieu of or in combination with the nano-FETs.

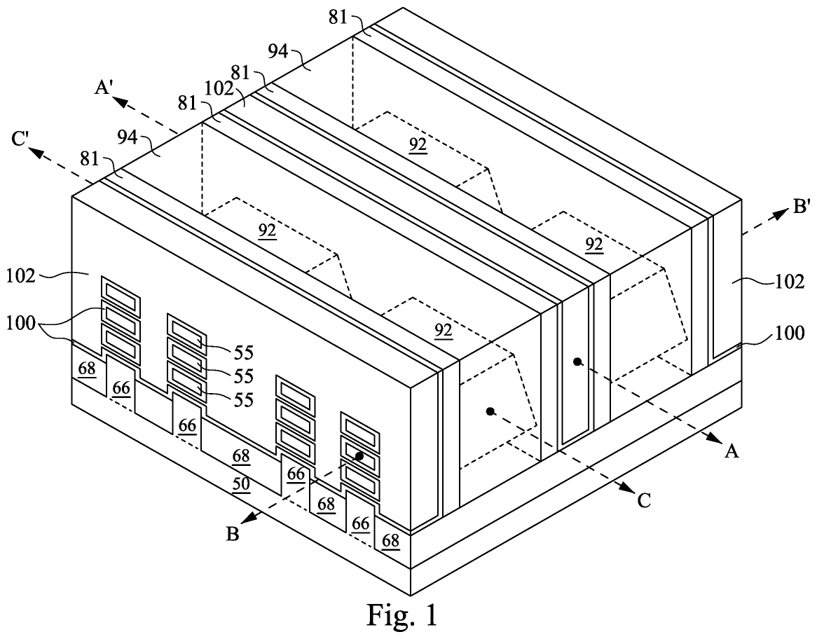

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 55 (e.g., nanosheets, nanowires, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portions extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100, and gate spacers 81 are disposed along sidewalls of the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context. One or more dielectric layers (e.g., interlayer dielectric (ILD) 94) may be formed over the epitaxial source/drain regions 92 between the gate dielectric layers 100/gate electrodes 102.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

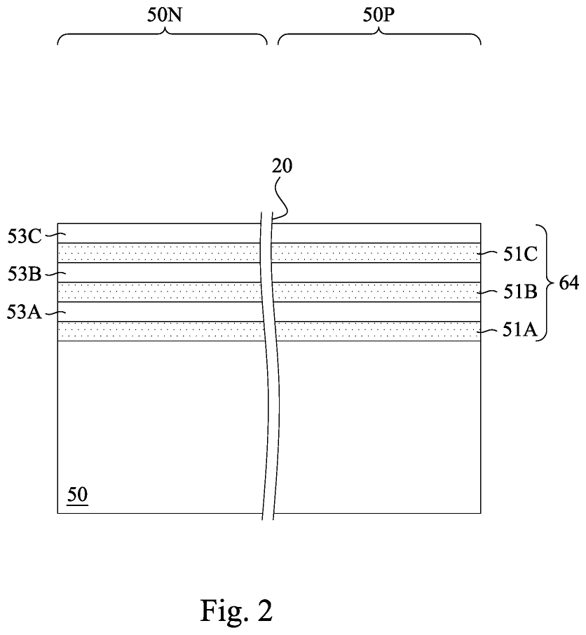

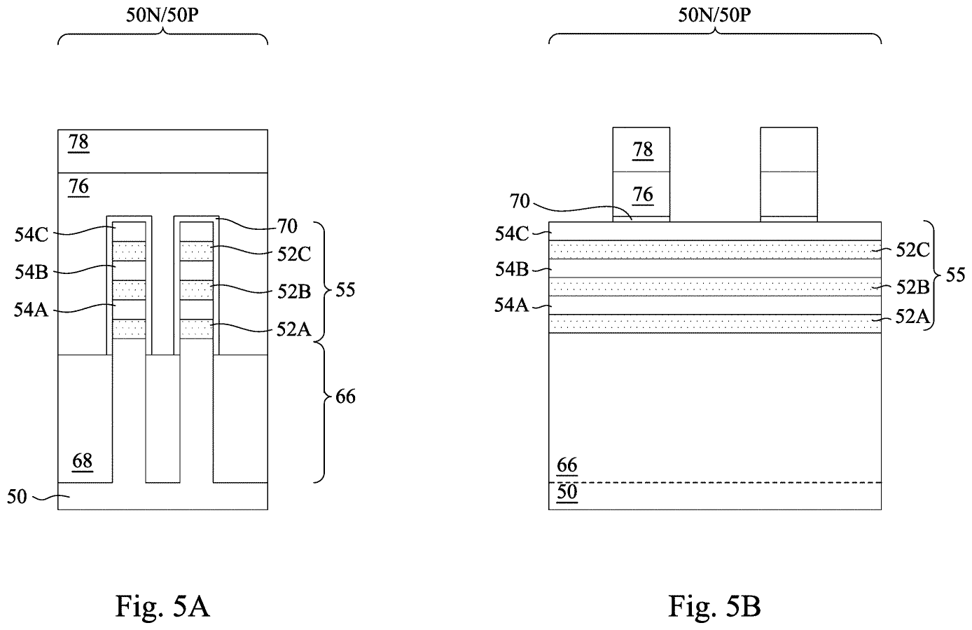

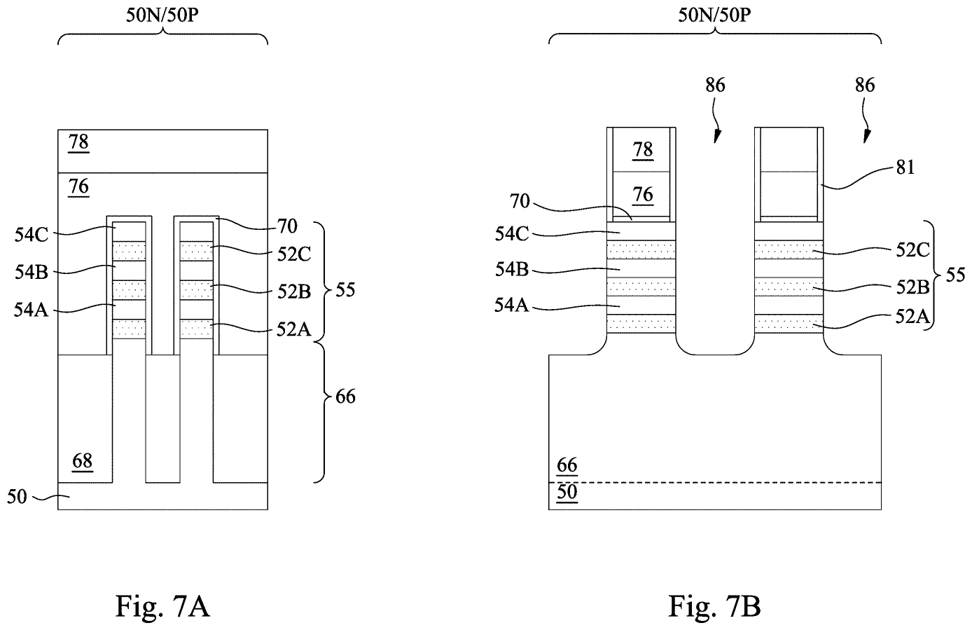

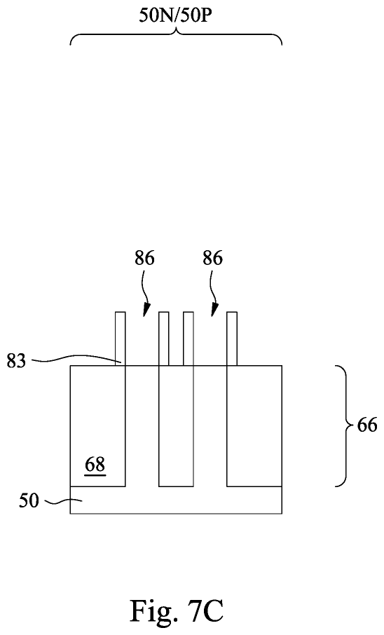

FIGS. 2 through 19C are cross-sectional views of intermediate stages in the manufacturing of nano-FETs, in accordance with some embodiments. FIGS. 2, 3, 4, 5A, 6A, 7A, 8A, 9A, 10A, 11A, 12A, 13A, 14A, 15A, 16A, 17A, 18A, and 19A illustrate reference cross-section A-A′ illustrated in FIG. 1. FIGS. 5B, 6B, 7B, 8B, 9B, 9C, 9D, 10B, 11B, 12B, 13B, 14B, 14C, 15B, 15C, 15D, 15E, 15F, 15G, 15H, 15I, 16B, 16C, 16D, 16E, 16F, 16G, 16H, 17B, 18B, and 19B illustrate reference cross-section B-B′ illustrated in FIG. 1. FIGS. 7C, 10C, 10D, 17C, 18C, and 19C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type region 50N or the p-type region 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

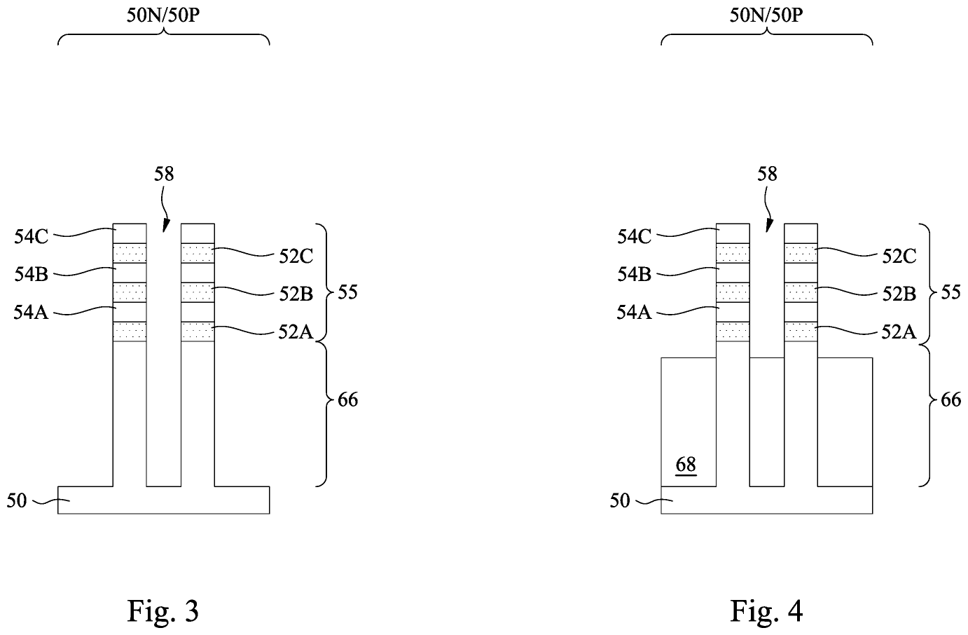

Referring now to FIG. 3, fins 66 are formed in the substrate 50 and nanostructures 55 are formed in the multi-layer stack 64 (shown in FIG. 2), in accordance with some embodiments. In some embodiments, the nanostructures 55 and the fins 66 may be formed in the multi-layer stack 64 (shown in FIG. 2) and the substrate 50, respectively, by etching trenches 58 in the multi-layer stack 64 (shown in FIG. 2) and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 (shown in FIG. 2) may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may be flat surfaces as illustrated, convex surfaces, concave surfaces (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over the top surfaces of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process. FIG. 4 describes the wells as being formed in the fins 66 and/or the nanostructures 55 after they have been patterned. Alternatively, the wells may be formed in the first semiconductor layers 51 and/or the substrate 50 prior to patterning the fins 66 and/or the nanostructures 55.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be made of silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

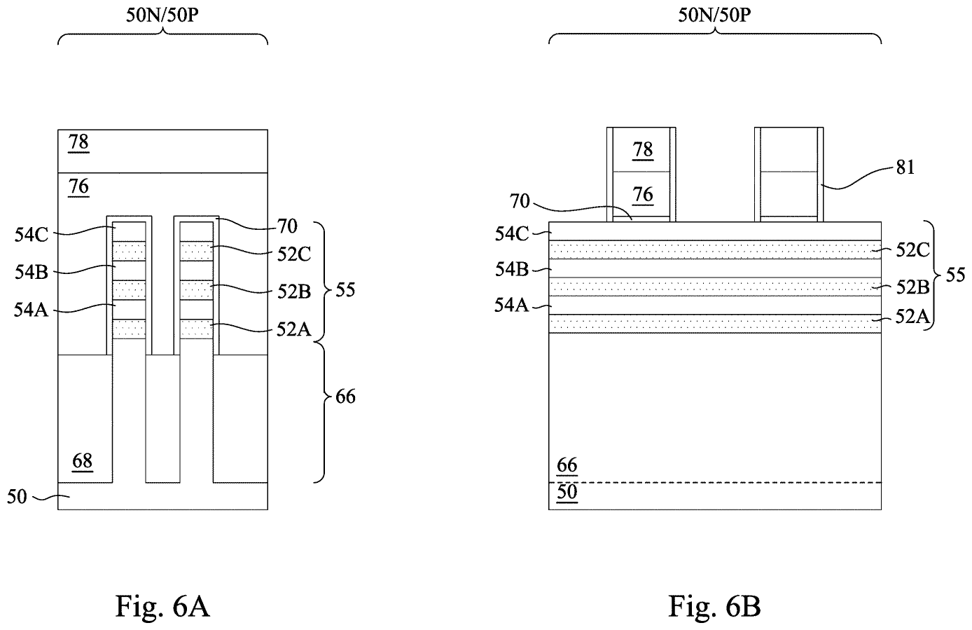

In FIGS. 6A and 6B, gate spacers 81 are formed over the nanostructures 55 and the STI regions 68, on exposed sidewalls of the masks 78 (if present), the dummy gates 76, and the dummy dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

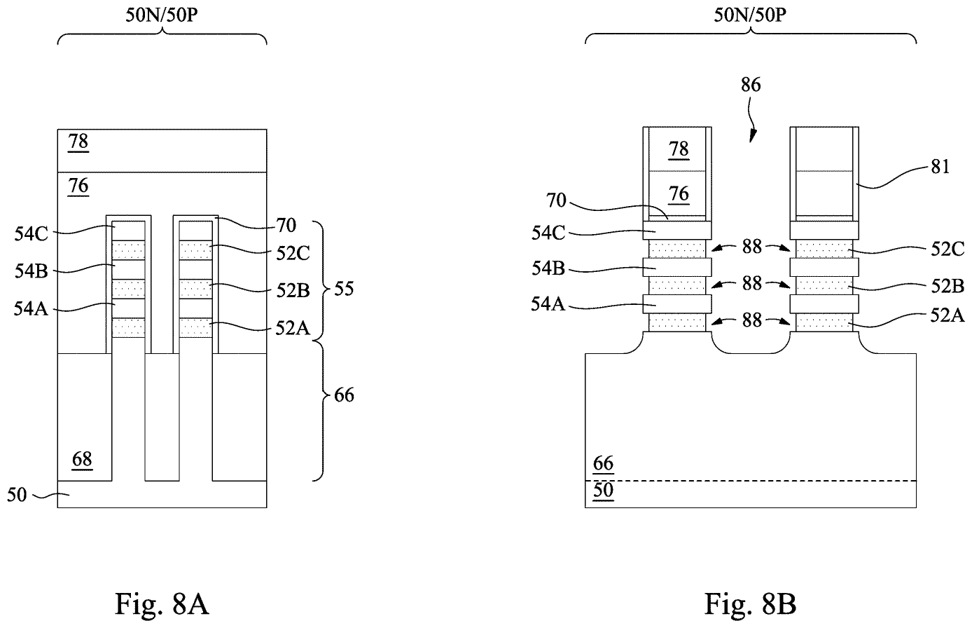

In FIGS. 8A and 8B, portions of sidewalls of the layers of the multi-layer stack 64 formed of the first semiconductor materials (e.g., the first nanostructures 52) exposed by the first recesses 86 are etched to form sidewall recesses 88. Although sidewalls of the first nanostructures 52 in sidewall recesses 88 are illustrated as being straight in FIG. 8B, the sidewalls may be concave or convex depending on the etching parameters used to form the sidewall recesses 88. The sidewalls may be etched using isotropic etching processes, such as dry etching, or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

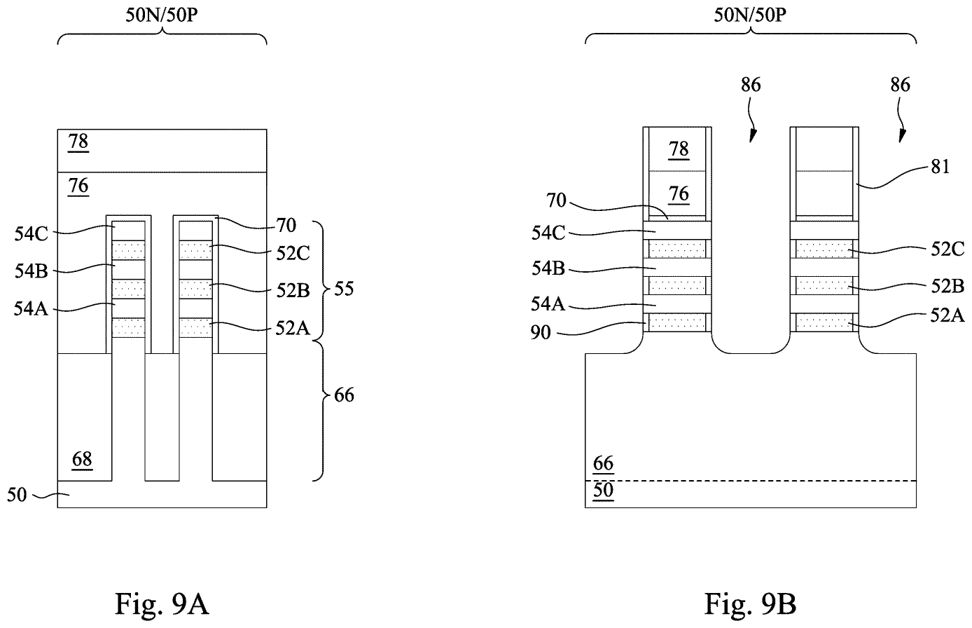

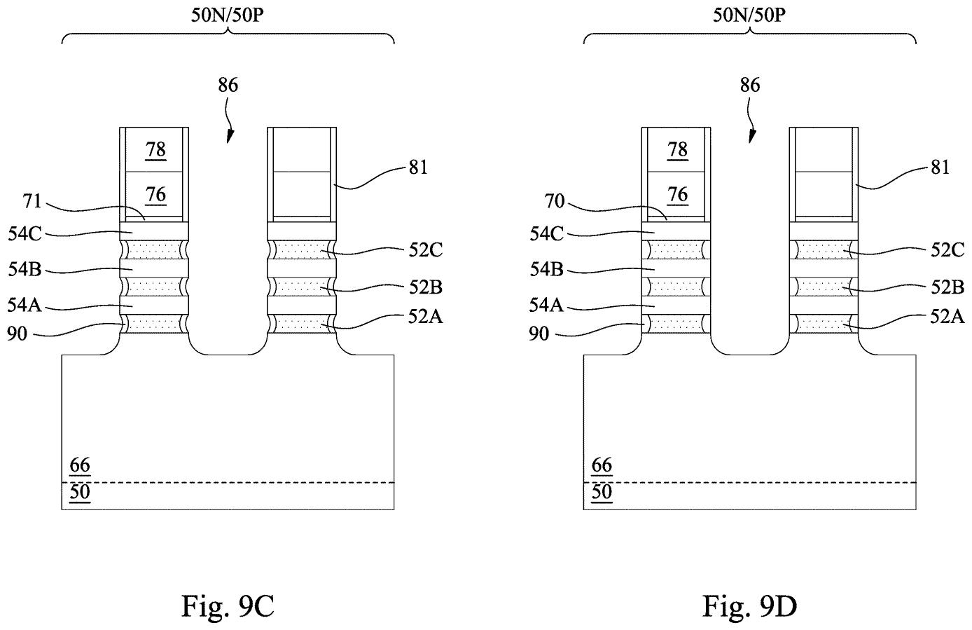

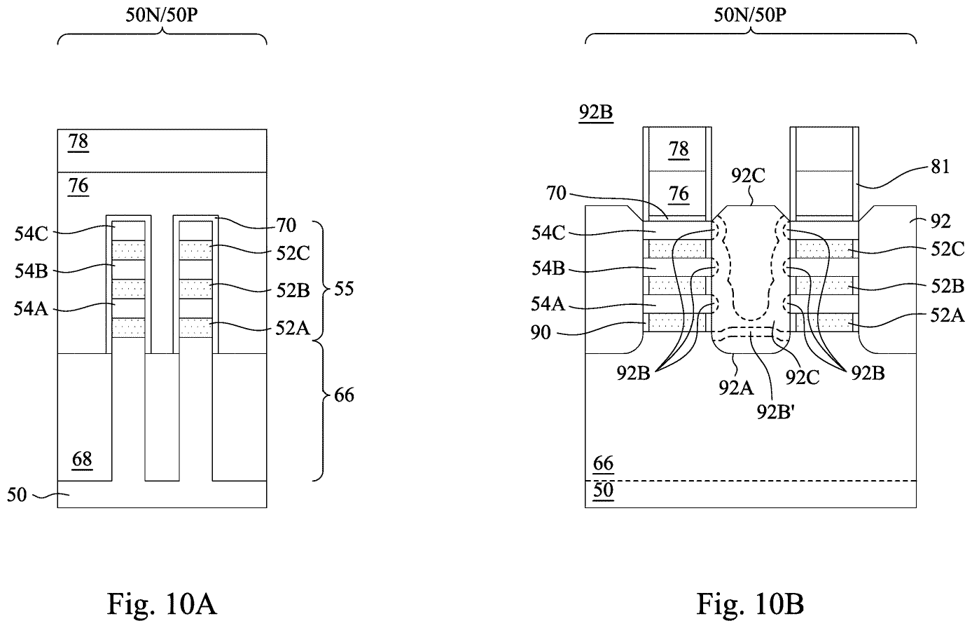

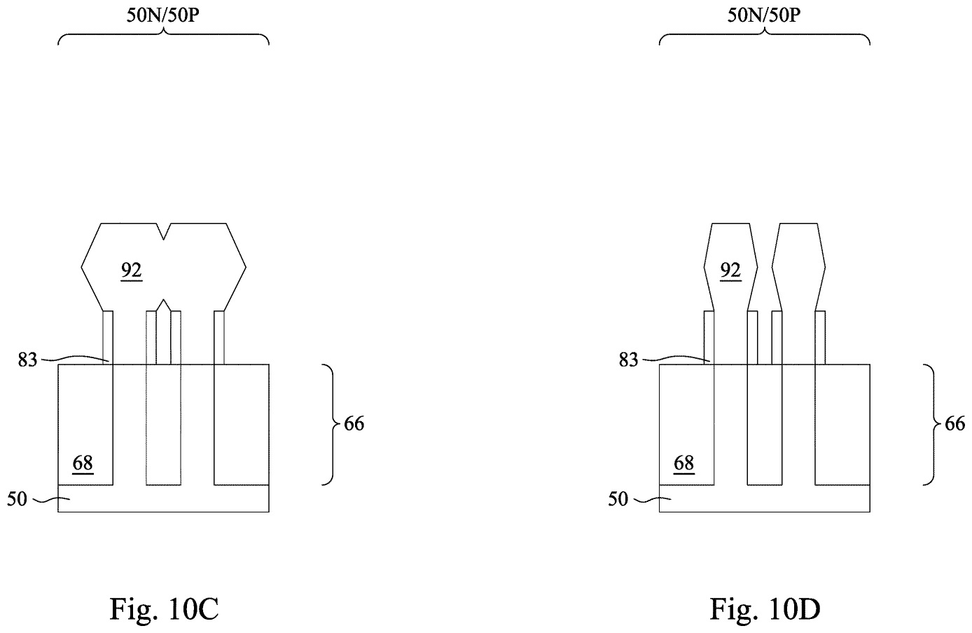

In FIGS. 9A and 9B, first inner spacers 90 are formed in the sidewall recess 88. The first inner spacers 90 may be formed by depositing an inner spacer layer (not separately illustrated) over the structures illustrated in FIGS. 8A and 8B. The first inner spacers 90 act as isolation features between subsequently formed source/drain regions and a gate structure. As will be discussed in greater detail below, source/drain regions will be formed in the first recesses 86, while the first nanostructures 52 will be replaced with corresponding gate structures. The first inner spacers 90 act to isolate the gate structures from the source/drain regions. The first inner spacers 90 may also be used to prevent damage to subsequently formed source/drain regions (such as the epitaxial source/drain regions 92, discussed below with respect to FIGS. 10A-10D) by subsequent etching processes, such as etching processes used to form gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be etched to form the first inner spacers 90. For example, the inner spacer layer may be etched by an anisotropic etching process, such as RIE, NBE, or the like.

Although outer sidewalls of the first inner spacers 90 are illustrated as being flush with sidewalls of the second nanostructures 54 in the n-type region 50N and flush with the sidewalls of the first nanostructures 52 in the p-type region 50P in FIG. 9B, the outer sidewalls of the first inner spacers 90 may extend beyond or be recessed from sidewalls of the second nanostructures 54 and/or the first nanostructures 52, respectively. Moreover, although the outer sidewalls of the first inner spacers 90 are illustrated as being straight in FIG. 9B, the outer sidewalls of the first inner spacers 90 may be concave or convex. As an example, FIG. 9C illustrates an embodiment in which sidewalls of the first nanostructures 52 are concave, outer sidewalls of the first inner spacers 90 are concave, and the first inner spacers 90 are recessed from sidewalls of the second nanostructures 54. As another example, FIG. 9D illustrates an embodiment in which sidewalls of the first nanostructures 52 are concave, outer sidewalls of the first inner spacers 90 are straight, and the first inner spacers 90 are flush from sidewalls of the second nanostructures 54.

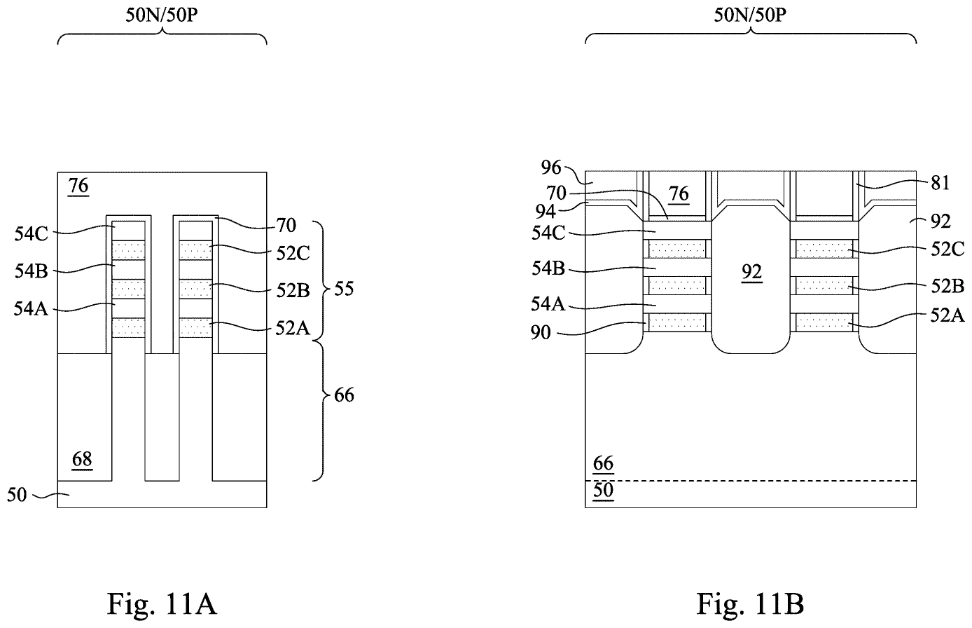

In FIGS. 10A-10D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the first nanostructures 52 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 10C. In other embodiments, adjacent epitaxial source/drain regions 92 remain separated after the epitaxy process is completed as illustrated by FIG. 10D. In the embodiments illustrated in FIGS. 10C and 10D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the fin spacers 83 may be omitted entirely, and the epitaxially grown region may extend to the top surface of the STI regions 68.

The epitaxial source/drain regions 92 may comprise one or more semiconductor material layers as illustrated by FIG. 10B. For example, the epitaxial source/drain regions 92 may comprise a first semiconductor material layer 92A, a second semiconductor material layer 92B, a third semiconductor material layer 92C, and a fourth semiconductor material 92D. Any number of semiconductor material layers may be used for the epitaxial source/drain regions 92.

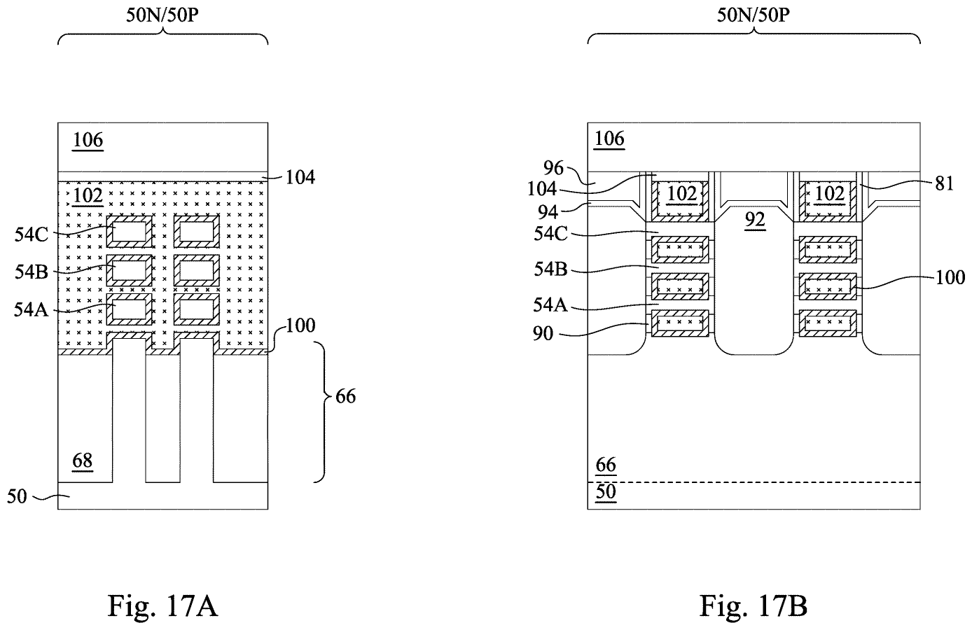

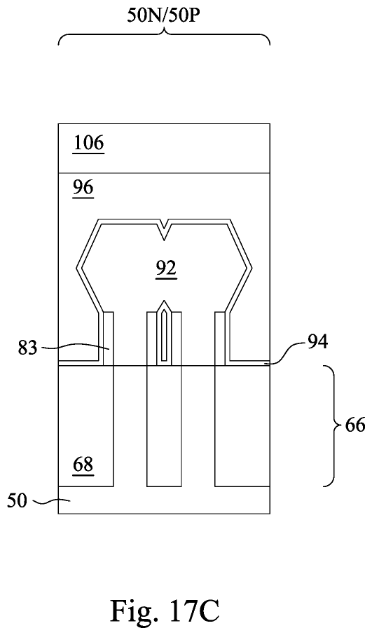

Each of the first semiconductor material layer 92A, the second semiconductor material layer 92B, the third semiconductor material layer 92C, and the fourth semiconductor material layer 92D may be formed of different semiconductor materials and may be doped to different dopant concentrations. For example, the first semiconductor material layer 92A may be a undoped or lightly doped layer that prevents or reduces diffusion of dopants from the overlying epitaxial layers (e.g., particularly the third and fourth semiconductor material layers 92C and 92D) into the underlying substrate 50. In a specific example, the first and second semiconductor material layers 92A and 92B may be silicon layers that are substantially free of germanium, and the third and fourth semiconductor material layers 92C and 92D may be silicon germanium layers. The second semiconductor material layer 92B may be high concentration, dopant layer (e.g., a high concentration boron-doped layer or the like) that is formed to increase etch selectivity along sidewalls of the second nanostructures 54 during subsequent oxide etching processes to reduce the risk of undesired etching. The oxide etching processes include processes to remove the sacrificial material 72 as described below in FIGS. 17A-17B. The second semiconductor material layer 92B may include lateral portions 92B′ that results from applying the doping process to the undoped or lightly doped first semiconductor material layer 92A. In embodiments in which the epitaxial source/drain regions 92 comprise four semiconductor material layers, the first semiconductor material layer 92A may be deposited, the second semiconductor material layer 92B may be formed by doping the first semiconductor material layer 92A with a suitable dopant and/or depositing the second semiconductor material layer 92B over the first semiconductor material layer 92A, the third semiconductor material layer 92C may be deposited over the second semiconductor material layer 92B, and the fourth semiconductor material layer 92D may be deposited over the third semiconductor material layer 92C. Other source/drain configurations are also possible in other embodiments. Details of the epitaxial source/drain regions 92 may be omitted in subsequent figures for ease of illustration.

In FIGS. 11A and 11B, a first interlayer dielectric (ILD) 96 is deposited over the structure illustrated in FIGS. 10A-10D, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

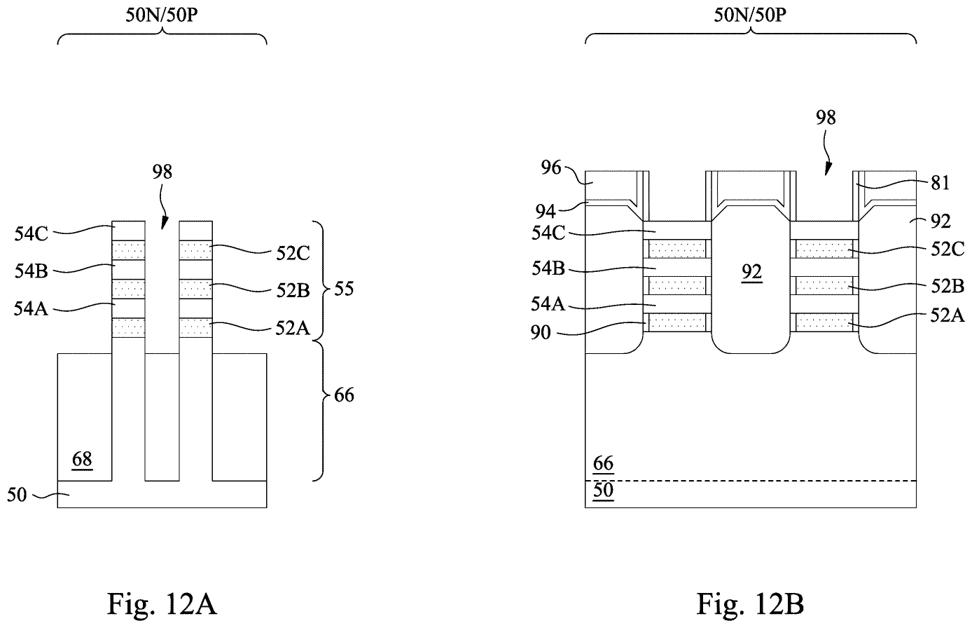

In FIGS. 12A and 12B, the dummy gates 76, and the masks 78 if present, are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

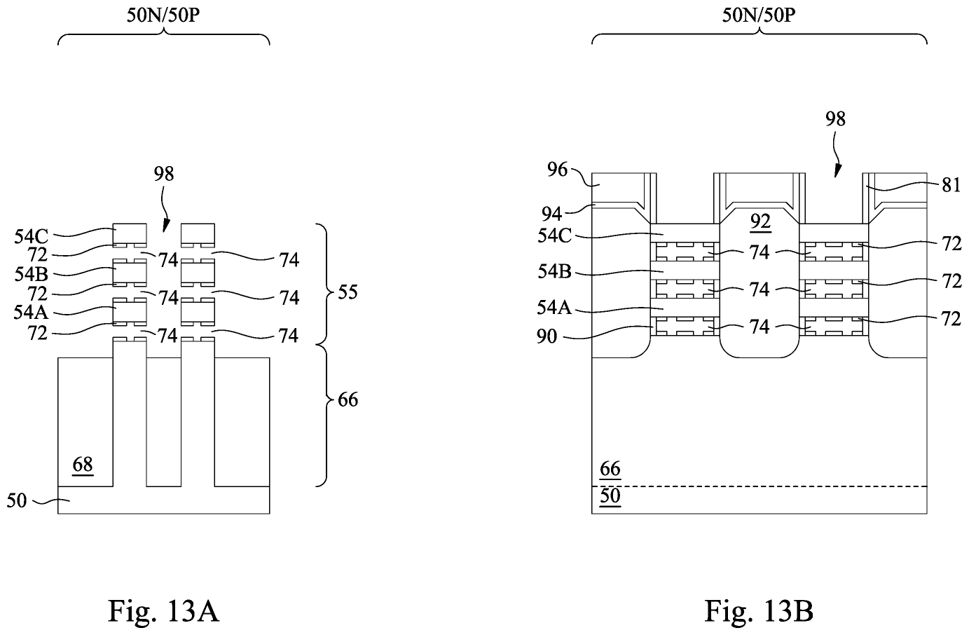

In FIGS. 13A and 13B, the first nanostructures 52 is removed, forming third recesses 74 that are connected to the second recesses 98. Removing the first nanostructures 52 may include performing an isotropic etching process such as dry etching or the like using etchants which are selective to the materials of the first nanostructures 52, while the second nanostructures 54 remain relatively unetched as compared to the first nanostructures 52. In embodiments in which the first nanostructures 52 include, e.g., SiGe, and the second nanostructures 54A-54C include, e.g., Si or SiC, dry etching with a chlorine-based etchant, or the like may be used to remove the first nanostructures 52. Although the first nanostructures 52 are removed, a residue 72 of the first nanostructures 52 may remain on surfaces of the second nanostructures 54 in the third recesses 74. For example, when the first nanostructures 52 include SiGe, the residue 72 may be germanium intermix residue.

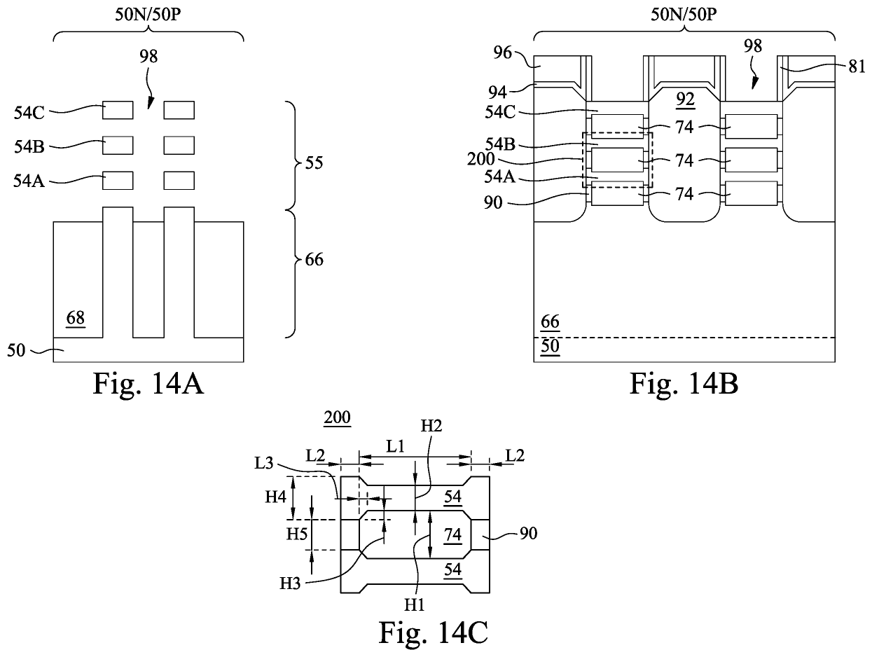

In FIGS. 14A-14C, the residue 72 is removed to improve the electrical performance of the resulting transistor devices. The residue 72 may be removed by a cleaning process, such as a wet etching process, a dry etching process, combinations thereof, or the like. For example, in embodiments where the residue 72 is a germanium intermix residue, the residue 72 may be removed by performing a wet etching process with an etchant comprising hydrogen fluoride (HF), DIO₃, NH₄OH, H₂O₂, combinations thereof, or the like. The wet etching process may remove the residue 72 directly or it may oxidize the residue 72. In embodiments where the residue 72 is oxidized, a subsequent oxide removal process may be performed to fully remove the residue 72. The oxide removal process may be performed by wet or dry etching, such as aqueous HF etching; fluorine radical etching with a fluorine-based gas (e.g., NF₃, SF₆, CF₄, OF₂, HF, or the like) that may be optionally mixed with a hydrogen-based gas (e.g., NH₃, H₂, H₂O, or the like); gas phase reaction etching (e.g., using HF and NH₃, HF and alkylamine, or the like); or the like.

Removing the residue 72 improves the electrical performance of the second nanostructures 54 as channel regions in the resulting transistor devices. However, removing the residue 72 may also roughen the surfaces of the second nanostructures 54 and/or surfaces of the inner spacers 90 in the third recesses 74. Further, removing the residue 72 may overetch portions of the second nanostructures 54 that are exposed by the third recesses 74 and/or the second recesses 98.

For example, FIG. 14C illustrates a detailed view of second nanostructures 54 and a third recess 74 in a region 200 of the structure of FIG. 14B. As detailed in FIG. 14C, after removing the residue 72, the third recesses 74 may have a height H1 that is greater than a height H5 of the inner spacers 90. The height H1 may refer to a maximum height of the third recesses 74 along the cross-section B-B′, and the height H1 may be measured in a center region of the third recess 74. In some embodiments, the height H1 of the third recess 74 may be in a range of 4 nm to 12 nm, such as 8 nm, and the height H4 of the inner spacers 90 may be in a range of 3 nm to 15 nm, such as 10 nm. Further, center regions of the second nanostructures 54 may be etched such that they have a height H2 that is less than a height H4 of edge regions of the second nanostructure 54. This height variance results from the edge regions of the second nanostructures 54 being masked by the inner spacers 90 while removing the residue 72. Further, the height H4 may refer to a maximum height of the second nanostructures 54 in the cross-section B-B′ while the height H2 may refer to a minimum height of the second nanostructures 54 in the cross-section B-B′. In some embodiments, the height H2 of the center regions of the second nanostructures 54 may be in a range of 2 nm to 8 nm, such as 5 nm, and the height H4 of the edge regions of the second nanostructures 54 may be in a range of 3 nm to 10 nm, such as in a range of 6 nm to 8 nm. A height difference between maximum and minimum heights L4, L2 of the second nanostructures 54 may be less than 6 nm in some embodiments.

As further illustrated in FIG. 14C, the center regions (e.g., etched portions) of the second nanostructures 54 and the third recesses 74 may each have a length L1. In some embodiments, the length L1 may be in a range of 5 nm to 30 nm, such as in a range of 16 nm to 20 nm. The length L1 may also correspond to portions of the second nanostructures 54 that will be subsequently surrounded by gate structures. Further, edge regions (e.g., unetched portions) of the second nanostructures and the inner spacers 90 may each have a length L2 that is less than L1. In some embodiments, the length L2 may be in a range of 2 nm to 8 nm, such as in a range of 4 nm to 6 nm. Corners of the third recesses 74 may be etched and slanted from the residue removal process, and corner regions of the third recesses 74 may have a height H3 and a length L3. In some embodiments, the height H3 may correspond to the height difference between maximum and minimum heights L4, L2 of the second nanostructures 54 and may be less than 6 nm. In some embodiments, the length L3 may be less than 6 nm, such as in a range of 2 nm to 4 nm. Other dimensions and profiles of the third recesses 74 may result from removing the residue 72 in other embodiments.

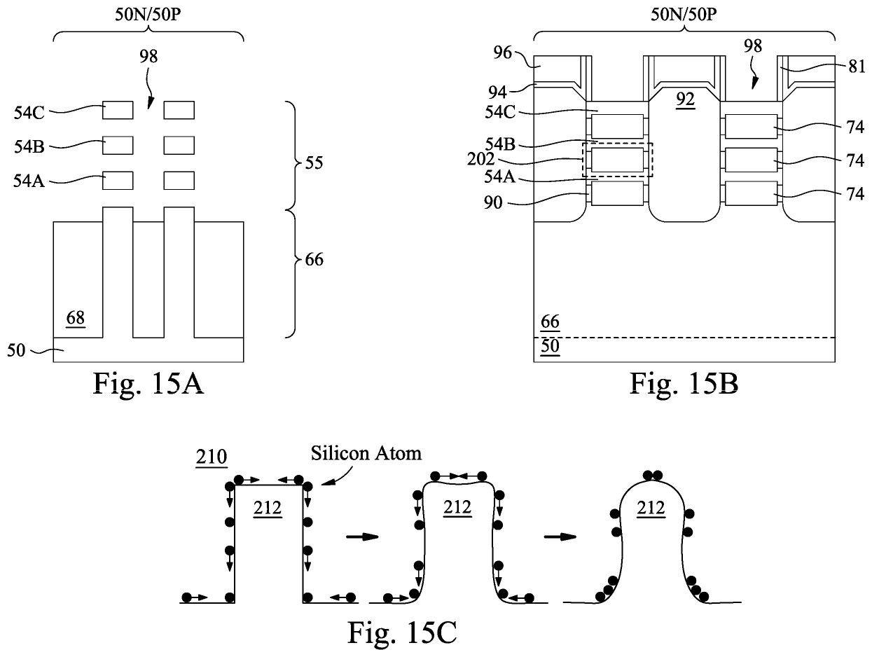

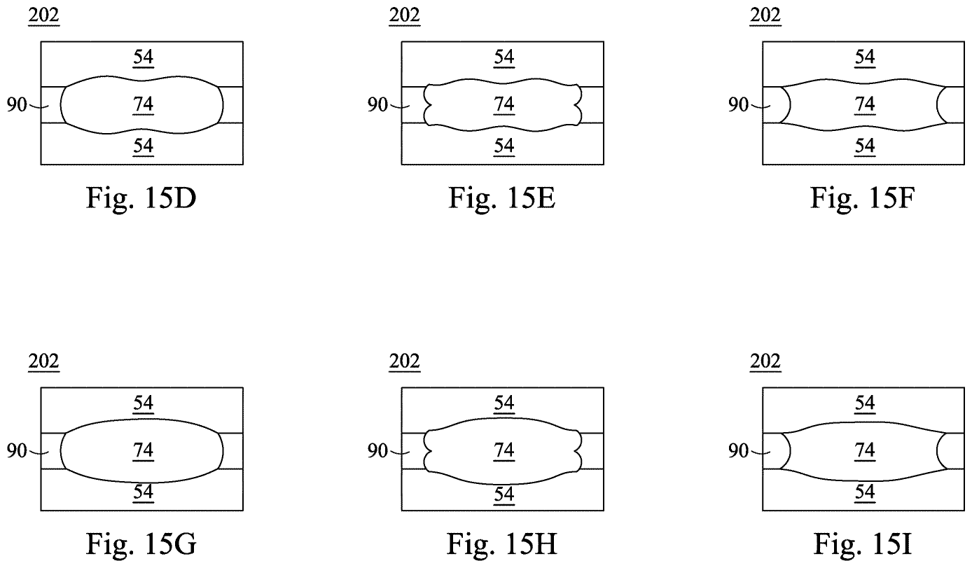

In FIGS. 15A-15H, a surface repair process is applied to the second nanostructures 54. The surface repair process may reduce surface roughness of the second nanostructures 54 and the inner spacers 90. The surface repair process may further increase a curvature of the second nanostructures 54 and the inner spacers 90 to achieve a desired profile of the third recesses 74, thereby defining a desired profile for the gate structures that are subsequently formed in the third recesses 74. As a result of the surface repair process, current crowding effects (CCE) at corners between the second nanostructures 54 and the subsequently formed gate structures can be reduced, thereby improving device performance. Further, a profile of the third recesses 74 can be modulated to achieve a desired threshold voltage (Vₜ) in the resulting device.

The surface repair process may include a thermal anneal process. For example, a thermal anneal may be performed at a temperature in a range of 400 °C to 900 °C in an ambient of N₂, H₂, He, or the like. Further, the thermal anneal may be performed at a relatively low pressure, such as in a range of 0.1 Torr to 300 Torr. It has been observed that by increasing a temperature and reducing a pressure the second nanostructures 54, such as in the above temperature/pressure ranges, diffusivity of silicon atoms of the second nanostructures 54 and the inner spacers 90 is increased, allowing for surface migration of the silicon atoms. This is schematically illustrated by the flow chart 210 of FIG. 15C. Specifically, FIG. 15C illustrates the changes in migration of silicon atoms on the surface of a bulk material 212 due to the application of temperature at a relatively low pressure, which results in an increased curvature of the surface of the bulk material 212. As a result, a curvature (roundness) of exposed surfaces of the second nanostructures 54 and inner spacers 90 can be increased, and surface roughness of the second nanostructures 54 and the inner spacers 90 can be reduced.

The surface repair process may further include an optional material deposition process that can be performed in combination with or in lieu of the thermal anneal process. The material deposition process may re-deposit a thin layer of semiconductor material (e.g., silicon) on exposed surfaces of the second nanostructures 54. In some embodiments, the material deposition process may comprise CVD, an epitaxial process, or the like that selectively deposits the semiconductor material on the exposed surfaces of the second nanostructures 54. In embodiments, where the re-deposited, semiconductor material is silicon, precursors of the re-deposition process may include silane, disilane, dichlorosilane, trisilane, or the like. In some embodiments, the re-deposited semiconductor material is relatively thin, such as in a range of 3 Å to 1 nm. The thin, re-deposited, semiconductor material reduces surface roughness of the second nanostructures 54 and may mitigate any unintentional over etching of the nanostructures 54 from the residue removal process. For example, the re-deposited material layer may have an improved material quality (e.g., be more crystalline) than the underlying core material of the second nanostructures 54. Further, the material deposition process may be performed at a temperature in a range of 400 °C to 600 °C and at a pressure in a range of 0.1 Torr to 300 Torr. It has been observed that performing the material deposition process in the above temperature and/or pressure ranges, diffusivity of silicon atoms of the second nanostructures 54 and the inner spacers 90 is increased, allowing for surface migration of silicon atoms that advantageously increases a curvature of surfaces in the third recesses 74.

Th surface repair process modifies a profile of the second nanostructures 54 and the inner spacers 90 and the corresponding third recesses 74. For example, FIGS. 15D-15I illustrate detailed views of the region 202 of FIG. 15B according to various embodiments. Specifically, the surface repair process may increase a curvature of the inner spacers 90, the second nanostructures 54, and the third recesses 74 to achieve any of the profiles illustrated by FIGS. 15D-15I. For example, the surface repair process may cause the inner spacers 90 to have an inward curvature (e.g., a concave profile as illustrated by FIGS. 15D and 15G) or an outward curvature (e.g., a convex profile as illustrated by FIGS. 15E, 15F, 15H, and 15I) in the third recesses 74. The inner spacers may have a single, continuous inward or outward curvature (e.g., as illustrated by FIGS. 15D, 15G, 15F, and 15I) or have a profile that includes multiple concave/convex portions (e.g., as illustrated by FIGS. 15E and 15H). Similarly, the surface repair process may cause surfaces of the second nanostructures 54 to have an inward curvature (e.g., a concave profile as illustrated by FIGS. 15G, 15H, and 15I) or an outward curvature (e.g., a convex profile as illustrated by FIGS. 15D, 15E, and 15F). Changing the profile of surfaces of the inner spacers 90 and the second nanostructures 54 may likewise change the curvature of the third recesses 74. Each of the specific profiles illustrated by FIGS. 15D-15I may be achieved by tuning the parameters of the surface repair process. In some embodiments, a specific profile is selected for the third recesses 74 (and the resulting gate structures) based on a desired threshold voltage of the resulting transistor device. Additionally, the change in curvature and/or re-deposition process may not significantly affect the dimensions of the third recesses 74, such that the dimensions of the third recesses 74, the second nanostructures 54, and the inner spacers 90 remain within the ranges discussed with respect to FIG. 14C even after the surface repair process.

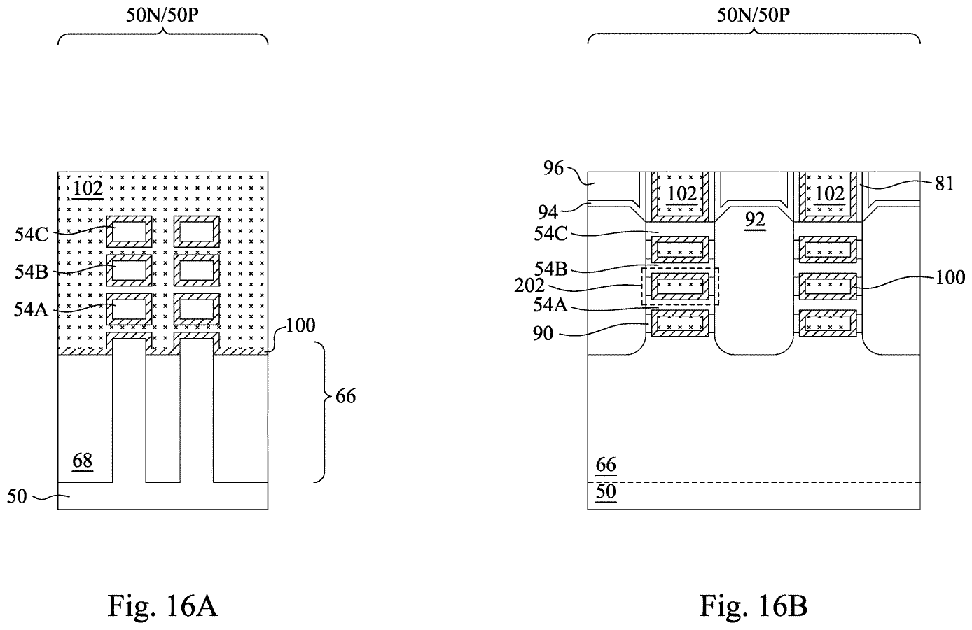

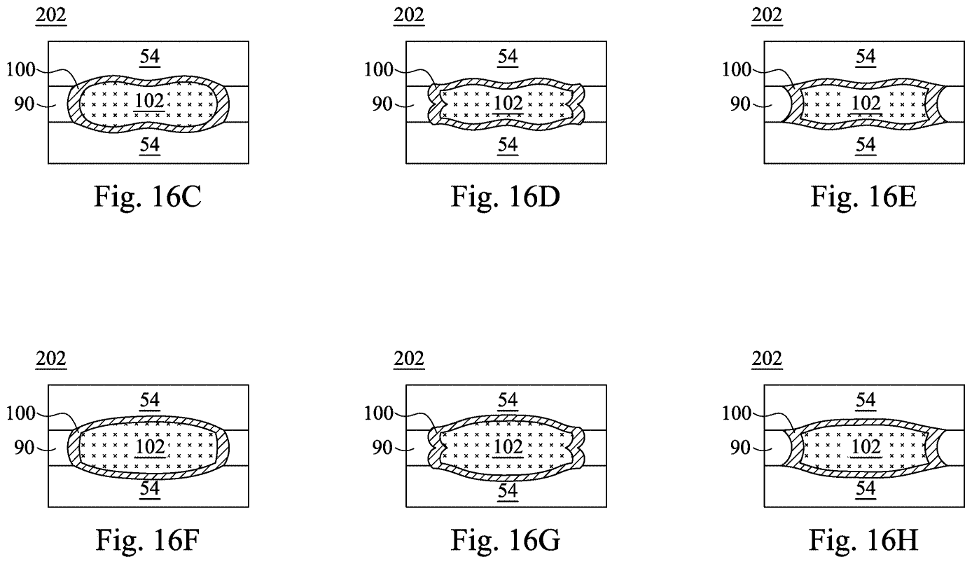

In FIGS. 16A-16H, gate dielectric layers 100 and gate electrodes 102 are formed for replacement gates. The gate dielectric layers 100 are deposited conformally in the second recesses 98 and the third recesses 74. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the Like.

The gate electrodes 102 are deposited over the gate dielectric layers 100, respectively, and fill the remaining portions of the second recesses 98 and the third recesses 74. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 16A-16H, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as gate structures 102/100.

FIGS. 16C-16H illustrate detailed views of the region 202 of FIG. 16B according to various embodiments. Portions of the gate structures 102/100 between the second nanostructures 54 are formed to fill the third recesses 74, and thus, also have a same profile as the third recesses 74 described above in FIGS. 15D-15I. Specifically, FIGS. 16C, 16D, 16E, 16F, 16G, and 16H have an analogous profile as described above in FIGS. 15D, 15E, 15F, 15G, 15H, and 15I, respectively. Lateral surfaces of the gate structures 100/102 may curve inwardly (e.g., be concave as illustrated in FIGS. 16C, 16D, and 16E) or curve outwardly (e.g., be convex as illustrated in FIGS. 16F, 16G, and 16H). Sidewalls of the gate structures 100/102 may also curve inwardly (e.g., be concave as illustrated in FIGS. 16E and 16H) or curve outwardly (e.g., be convex as illustrated in FIGS. 16C, 16F, 16D, and 16G). Dimensions of the gate structures 102/100 may fall in the ranges described above with respect to the third recesses 74 in FIG. 14C. For example, heights of center regions of the gate structures 102/100 may be greater than heights of edge regions of the gate structures 102/100.

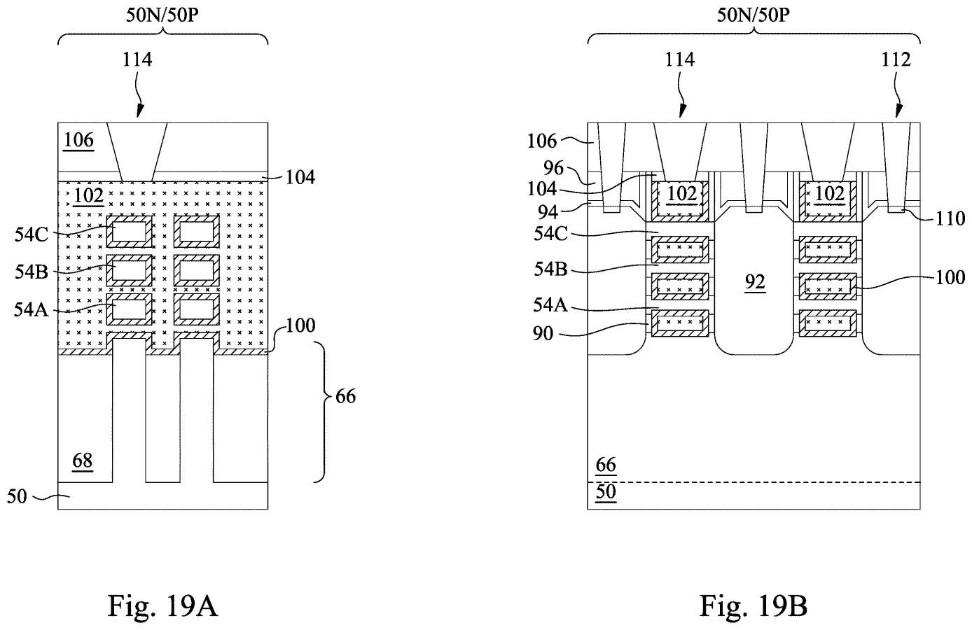

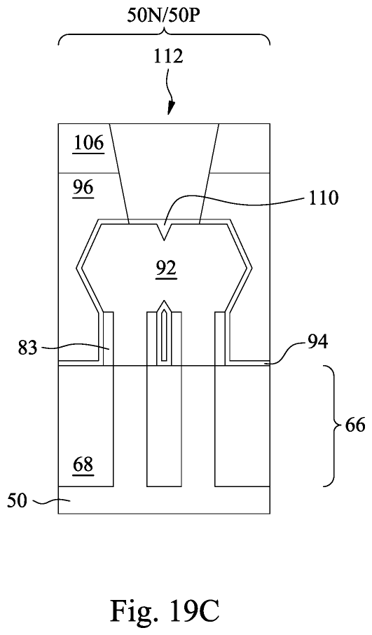

In FIGS. 17A-17C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 19A-19C) penetrate through the gate mask 104 to contact the top surface of the recessed gate electrodes 102.

As further illustrated by FIGS. 17A-17C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

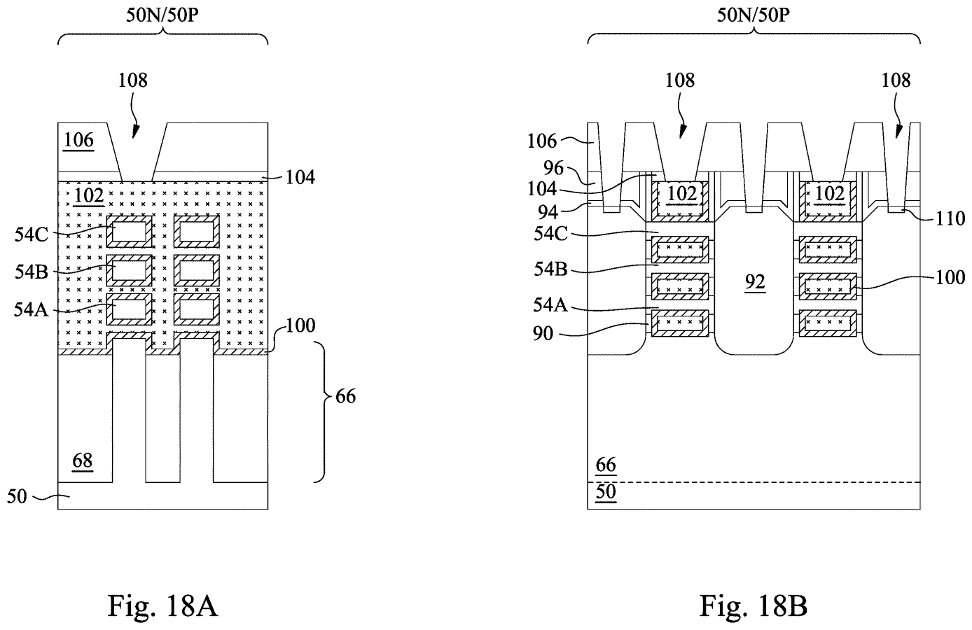

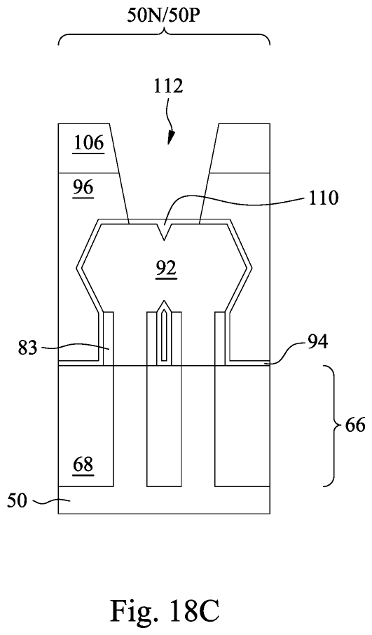

In FIGS. 18A-18C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 18B illustrates the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 19A-19C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

Various embodiments perform a surface repair process on nanostructures to improve the surface property and/or profile of the nanostructures after sacrificial nanostructures are etched away. The surface repair process may include an anneal process and/or a semiconductor re-deposition process that increases the curvature of the nanostructures and reduces surface roughness of the nanostructures. As a result, various embodiments provide reduced surface residue and improved device performance (e.g., reduced current crowding effect (CCE) at corners between the first nanostructures and the gate structures). Further, the surface repair process may be used to define a desired profile of the gate structures to achieve a desired threshold voltage.

In some embodiments. a method includes forming a plurality of nanostructures, the plurality of nanostructures comprising first nanostructures that are alternatingly stacked with second nanostructures; removing the first nanostructures from the plurality of nanostructures to define recesses between the second nanostructures; after removing the first nanostructures, performing a surface repair process on the second nanostructures, wherein the surface repair process increases a curvature of surfaces of the second nanostructures in the recesses; and forming a gate structure in the recesses around the second nanostructures. Optionally, in some embodiments, the surface repair process comprises performing a thermal anneal process on the second nanostructures. Optionally, in some embodiments, the thermal anneal process is performed a temperature in a range of 400 °C to 900 °C. Optionally, in some embodiments, the thermal anneal process is performed at a pressure in a range of 0.1 Torr to 300 Torr. Optionally, in some embodiments, the surface repair process comprises performing a material deposition process that deposits a semiconductor material on the second nanostructures. Optionally, in some embodiments, the material deposition process is performed a temperature in a range of 400 °C to 600 °C and at a pressure in a range of 0.1 Torr to 300 Torr. Optionally, in some embodiments, the semiconductor material that is deposited on the second nanostructures by the material deposition process has a thickness in a range of 3 Å to 1 nm. Optionally, in some embodiments, removing the first nanostructures leaves a semiconductor residue on surfaces of the second nanostructures, and wherein the method further comprises performing a cleaning process to remove the semiconductor residue before performing the surface repair process. Optionally, in some embodiments, prior to removing the first nanostructures, the method further comprises: recessing the first nanostructures; and forming inner spacers on the first nanostructures, wherein the surface repair process increases a curvature of surfaces of the inner spacers in the recesses.

In some embodiments, a method includes forming a second nanostructure between a first nanostructure and a third nanostructure, wherein the first nanostructure, the second nanostructure, and the third nanostructure are vertically stacked; removing the second nanostructure to define a recess between the first nanostructure and the third nanostructure, wherein removing the second nanostructure leaves a semiconductor residue on surfaces of the first nanostructure and the third nanostructure in the recess; performing an etching process to remove the semiconductor residue; after performing the etching process, performing a surface repair process in the recess, wherein the surface repair process increases a curvature of one or more surfaces in the recess; and forming a gate structure in the recess around the first nanostructure and the third nanostructure. Optionally, in some embodiments, the method further includes recessing sidewalls the second nanostructure from sidewalls of the first nanostructure and the third nanostructure; and forming a first inner spacer and a second inner spacer on the sidewalls of the second nanostructure, wherein removing the second nanostructure further defines the recess between the first inner spacer and the second inner spacer. Optionally, in some embodiments, the surface repair process increases a curvature of sidewalls of the first inner spacer and the second inner spacer. Optionally, in some embodiments, the surface repair process deposits a semiconductor material on the surfaces of the first nanostructure and the third nanostructure in the recess. Optionally, in some embodiments, the surface repair process is a thermal anneal process. Optionally, in some embodiments, the semiconductor residue is germanium intermix residue.

In some embodiments, a device includes a first nanostructure extending from a first source/drain region to a second source/drain region; a second nanostructure extending from the first source/drain region to the second source/drain region; and a gate structure between the first nanostructure and the second nanostructure, wherein a center region of the gate structure has a height than an edge region of the gate structure, and wherein the gate structure has a curved lateral surface at an interface between the first nanostructure and the gate structures. Optionally, in some embodiments, the curved lateral surface is concave. Optionally, in some embodiments, the curved lateral surface is convex. Optionally, in some embodiments, the device further includes an inner spacer on a sidewall of the gate structure, wherein the gate structure has a curved sidewall at an interface between the inner spacer and the gate structure, wherein the curved sidewall is concave. Optionally, in some embodiments, the device further includes an inner spacer on a sidewall of the gate structure, wherein the gate structure has a curved sidewall at an interface between the inner spacer and the gate structure, wherein the curved sidewall is convex.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a sacrificial nanostructure between a first nanostructure and a second nanostructure;
forming source/drain regions adjoining the first nanostructure and the second nanostructure;
removing the sacrificial nanostructure to form a recess between the first nanostructure and the second nanostructure, wherein after removing the sacrificial nanostructure, an intermix residue remains on the first nanostructure and the second nanostructure in the recess;
performing a cleaning process to remove the intermix residue;
after the cleaning process, performing a treatment process that changes a first curvature of the first nanostructure and a second curvature of the second nanostructure in the recess; and
forming a gate structure in the recess around the first nanostructure and the second nanostructure.

2. The method of claim 1, wherein the treatment process increases the first curvature of the first nanostructure and the second curvature of the second nanostructure.

3. The method of claim 1, wherein the treatment process comprises a thermal anneal process.

4. The method of claim 3, wherein the thermal anneal process is performed at a temperature in a range of 400 °C to 900 °C.

5. The method of claim 3, wherein the thermal anneal process is performed at a pressure in a range of 0.1 Torr to 300 Torr.

6. The method of claim 1, wherein the treatment process is a deposition process that grows a first additional semiconductor material on the first nanostructure and a second additional semiconductor material on the second nanostructure, wherein after the treatment process, the first nanostructure comprises the first additional semiconductor material and the second nanostructure comprises the second additional semiconductor material.

7. The method of claim 6, wherein the deposition process is performed at a temperature in a range of 400 °C to 600 °C and at a pressure in a range of 0.1 Torr to 300 Torr.

8. The method of claim 6, wherein the first additional semiconductor material has a thickness in a range of 3 Å to 1 nm.

9. The method of claim 6, wherein the first additional semiconductor material is more crystalline than a semiconductor material of the first nanostructure that the first additional semiconductor material is deposited on.

10. A method comprising:
forming a second nanostructure between a first nanostructure and a third nanostructure, wherein the first nanostructure, the second nanostructure, and the third nanostructure are vertically stacked;
etching a source/drain recess through the first nanostructure, the second nanostructure, and the third nanostructure;
recessing a sidewall of the second nanostructure through the source/drain recess;
forming an inner spacer on a recessed sidewall of the second nanostructure;
epitaxially growing a source/drain region in the source/drain recess;
forming a gate recess that extends between the first nanostructure and the third nanostructure, wherein forming the gate recess comprises removing the second nanostructure, and wherein removing the second nanostructure leaves a semiconductor residue on surfaces of the first nanostructure and the third nanostructure in the gate recess;
performing a cleaning process to remove the semiconductor residue;
after performing the cleaning process, performing a surface repair process in the gate recess, wherein the surface repair process reduces a surface roughness of the first nanostructure, the third nanostructure, or the inner spacer in the gate recess; and
forming a gate structure in the gate recess, wherein the gate structure wraps around the first nanostructure and the third nanostructure.

11. The method of claim 10, wherein the surface repair process increases a curvature of a surface of the first nanostructure facing the third nanostructure.

12. The method of claim 10, wherein the surface repair process increases a curvature of a surface of the inner spacer between the first nanostructure and the third nanostructure.

13. The method of claim 10, wherein the surface repair process deposits a semiconductor material on the surfaces of the first nanostructure and the third nanostructure in the gate recess.

14. The method of claim 10, wherein the surface repair process is a thermal anneal process.

15. The method of claim 10, wherein the semiconductor residue is germanium intermix residue.

16. A device comprising:
a first nanostructure and a second nanostructure extending from a first source/drain region to a second source/drain region in a first cross-sectional view;
a gate structure around the first nanostructure and the second nanostructure in a second cross-sectional view that is perpendicular to the first cross-sectional view, wherein a portion of the gate structure is disposed between the first nanostructure and the second nanostructure in the first cross-sectional view, wherein a first interface between the portion of the gate structure and the first nanostructure is curved; and
an inner spacer between the portion of the gate structure and the first source/drain region, wherein a second interface between the inner spacer and the portion of the gate structure is curved.

17. The device of claim 16, wherein the first interface is concave.

18. The device of claim 16, wherein the first interface is convex.

19. The device of claim 16, wherein a center of the first interface is higher than a top surface of the inner spacer.

20. The device of claim 16, wherein the second interface comprises a plurality of concave regions.
